(19) United States
(12) Patent Application Publication
(10) Pub. No.: US 2025/0138349 A1
(43) Pub. Date: May 1, 2025

(54) OPTICAL ELEMENT AND LASER MODULE

(71) Applicant: TDK Corporation, Tokyo (JP)

(72) Inventors: Yasuhiro TAKAGI, Tokyo (JP); Hiroki Hara, Tokyo (JP); Atsushi Shimura, Tokyo (JP); Jiro Yoshinari, Tokyo (JP)

(73) Assignee: TDK Corporation, Tokyo (JP)

(21) Appl. No.: 18/883,037

(22) Filed: Sep. 12, 2024

(30) Foreign Application Priority Data
Oct. 27, 2023 (JP) 2023-184917

(51) Int. Cl. G02F 1/035; G02F 1/01

(52) U.S. Cl. CPC G02F 1/0353; G02F 1/0142

(57) ABSTRACT

A core layer of an optical element includes a second conversion portion that converts a polarization mode of light from a TE1 mode to a TE0 mode. The second conversion portion includes: a splitting portion that splits the light in the TE1 mode incident from the first conversion portion into first split light in the TE0 mode and second split light in the TE0 mode which are in opposite phases; a coupling portion that couples the first split light that has propagated through a first branch waveguide and the second split light that has propagated through a second branch waveguide to emit the light in the TE0 mode; and a phase adjustment unit that adjusts a phase difference between the first split light and the second split light. The first branch waveguide and the second branch waveguide are arranged in a second direction.

### CROSS-REFERENCE TO RELATED APPLICATION

This application claims the benefit of priority from Japanese Patent Application No. 2023-184917 filed with the Japan Patent Office on Oct. 27, 2023, the entire contents of which are incorporated herein by reference.

### TECHNICAL FIELD

The present disclosure relates to an optical element and a laser module.

### BACKGROUND

The polarization mode of light propagating through the optical waveguide includes a transverse electric (TE) mode, which is a polarization mode having a main electric field in a direction parallel to the substrate, and a transverse magnetic (TM) mode, which is a polarization mode having a main electric field in a direction perpendicular to the substrate. An optical waveguide element for converting these polarization modes is known. For example, Japanese Unexamined Patent Application Publication No. 2021-196393 discloses a mode conversion element including a polarization rotation portion for converting light in the TM0 mode into light in the TE1 mode and a mode order conversion portion for converting light in the TE1 mode into light in the TE0 mode.

### SUMMARY

An optical modulator for converting an electric signal into an optical signal by modulating the light intensity of laser light is known. For example, it is possible to modulate the light intensity of the light of the TE0 mode converted by the mode conversion element by providing an optical modulator subsequent to the mode conversion element described in Japanese Unexamined Patent Application Publication No. 2021-196393. However, since the optical modulator is provided in addition to the mode conversion element, the size of the device may be increased.

The present disclosure describes an optical element and a laser module which can be reduced in size.

An optical element according to one aspect of the present disclosure includes: a substrate including a main surface; and a core layer provided on the main surface and made of a material having an electro-optic effect. The core layer includes a mode converter that converts a polarization mode of light from a TM0 mode to a TE0 mode. The mode converter includes: a first conversion portion that converts the polarization mode of the light from the TM0 mode to a TE1 mode; and a second conversion portion that converts the polarization mode of the light from the TE1 mode to the TE0 mode. The second conversion portion includes: a splitting portion that splits the light in the TE1 mode incident from the first conversion portion into first split light in the TE0 mode and second split light in the TE0 mode, which are in opposite phases; a first branch waveguide extending in a first direction along the main surface, through which the first split light propagates; a second branch waveguide extending in the first direction, through which the second split light propagates; a coupling portion that couples the first split light that has propagated through the first branch waveguide and the second split light that has propagated through the second branch waveguide to emit the light in the TE0 mode; and a phase adjustment unit that adjusts a phase difference between the first split light and the second split light. The first branch waveguide and the second branch waveguide are arranged in a second direction intersecting the first direction.

In the optical element, the polarization mode of the light is converted from the TM0 mode to the TE1 mode by the first conversion portion, and the polarization mode of the light is converted from the TE1 mode to the TE0 mode by the second conversion portion. In the second conversion portion, the light in TE1 mode incident from the first conversion portion is split into the first split light in TE0 mode and the second split light in TE0 mode having opposite phases, the phase difference between the first split light and the second split light is adjusted, and the first split light and the second split light are coupled, whereby the light in TE0 mode is emitted. Since the light intensity of the light emitted from the coupling portion can be changed in accordance with the phase difference between the first split light and the second split light, the second conversion portion can also function as an optical modulator. Accordingly, since there is no need to provide an optical modulator, the size of the optical element can be reduced.

The phase adjustment unit may include: a signal electrode disposed between the first branch waveguide and the second branch waveguide; and a first ground electrode and a second ground electrode disposed so as to sandwich the first branch waveguide and the second branch waveguide in the second direction. An optical axis of the material constituting the core layer may extend in the second direction. According to the above configuration, the first branch waveguide is disposed between the signal electrode and the first ground electrode, and the second branch waveguide is disposed between the signal electrode and the second ground electrode. Therefore, when a voltage is applied between the signal electrode and each ground electrode, a voltage is applied to the first branch waveguide and the second branch waveguide in the second direction. The polarization mode of the first split light propagating through the first branch waveguide is the TE0 mode, and the polarization mode of the second split light propagating through the second branch waveguide is the TE0 mode. Accordingly, in the first branch waveguide, a voltage is applied in the direction of the optical axis of the material constituting the core layer, and the direction of the main electric field of the light propagating through the first branch waveguide aligns with the direction of the optical axis, so that a large electro-optic effect can be obtained. Similarly, in the second branch waveguide, a voltage is applied in the direction of the optical axis of the material constituting the core layer, and the direction of the main electric field of the light propagating through the second branch waveguide aligns with the direction of the optical axis, so that a large electro-optic effect can be obtained. As a result, the modulation efficiency in the second conversion portion can be improved.

The light may be visible light. In this case, the polarization mode of the visible light can be converted from the TM0 mode to the TE0 mode.

A length of the splitting portion in the first direction may be 40 μm or more and 64 μm or less. A length of the splitting portion in the second direction may be 3.0 μm or more and 3.5 μm or less. In this case, it is possible to reduce the loss of light intensity in the conversion from the TE1 mode to the TE0 mode. Accordingly, the conversion efficiency from the TE1 mode to the TE0 mode can be improved.

The core layer may further include: a first mode converter which is the mode converter that converts a polarization mode of red light from the TM0 mode to the TE0 mode; a second mode converter which is the mode converter that converts a polarization mode of green light from the TM0 mode to the TE0 mode; a third mode converter which is the mode converter that converts a polarization mode of blue light from the TM0 mode to the TE0 mode; and a multiplexer that multiplexes the red light, the green light, and the blue light to emit laser light. In order to output full-color laser light by multiplexing the red light, the green light, and the blue light, it is necessary to adjust the light intensity of light of each color corresponding to the color to be output. According to the above configuration, since the light intensity of the red light, the light intensity of the green light, and the light intensity of the blue light are modulated by the second conversion portion of each mode converter, it is possible to output full-color laser light.

A laser module according to another aspect of the present disclosure includes: the above-described optical element; a first light source that emits the red light in the TM0 mode; a second light source that emits the green light in the TM0 mode; and a third light source that emits the blue light in the TM0 mode. Since the laser module includes the above-described optical element, the laser module can be reduced in size.

According to each aspect and each embodiment of the present disclosure, it is possible to reduce the size of an optical element and a laser module.

### BRIEF DESCRIPTION OF THE DRAWINGS

FIG. 1 is a perspective view showing an appearance of a near-eye wearable device to which a laser module according to an embodiment is applied.

FIG. 2 is a configuration diagram schematically showing the retinal projection device shown in FIG. 1.

FIG. 3 is a plan view of the laser module shown in FIG. 2.

FIG. 4 is a cross-sectional view taken along the line IV-IV of FIG. 3.

FIG. 5 is an enlarged view of a part of the mode converter shown in FIG. 3.

FIG. 6 is a cross-sectional view taken along the line VI-VI of FIG. 5.

FIG. 7 is an enlarged view of the modulator shown in FIG. 3.

FIG. 8 is a cross-sectional view taken along the line VIII-VIII of FIG. 7.

### DETAILED DESCRIPTION

Hereinafter, embodiments of the present disclosure will be described in detail with reference to the drawings. In the description of the drawings, the same elements are denoted by the same reference numerals, and redundant description will be omitted. In each figure, an XYZ coordinate system may be shown. The Y-axis direction (second direction) is a direction intersecting (for example, orthogonal to) the X-axis direction (first direction) and the Z-axis direction. The Z-axis direction is a direction intersecting (for example, orthogonal to) the X-axis direction and the Y-axis direction. In the present specification, the numerical ranges indicated by “to” represent ranges that include the values described before and after “to” as the minimum and maximum values, respectively. The individually described upper and lower limit values can be combined arbitrarily.

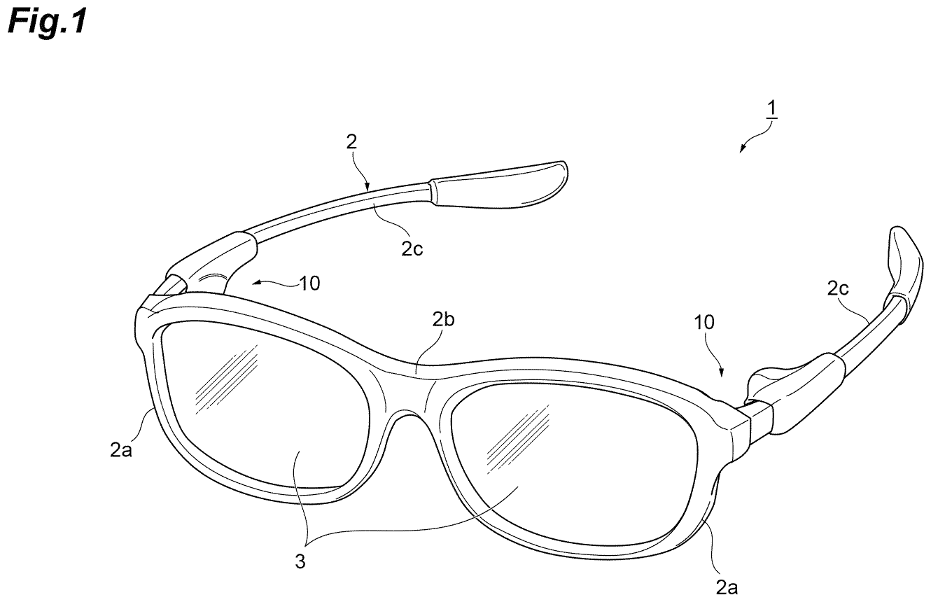

An application example of a laser module according to an embodiment will be described with reference to FIG. 1. FIG. 1 is a perspective view showing an appearance of a near-eye wearable device to which a laser module according to an embodiment is applied. The near-eye wearable device 1 shown in FIG. 1 is a device that projects images onto the retina of a user wearing the near-eye wearable device 1. The near-eye wearable device 1 is, for example, a head-mounted device, and may take the form of an eyeglass type, a goggle type, a hat type, a helmet type, or the like. Examples of the near-eye wearable device 1 include smart glasses such as augmented reality (AR) glasses, virtual reality (VR) glasses, and mixed reality (MR) glasses. The near-eye wearable device 1 includes a frame 2, a lens 3, and a retinal projection device 10.

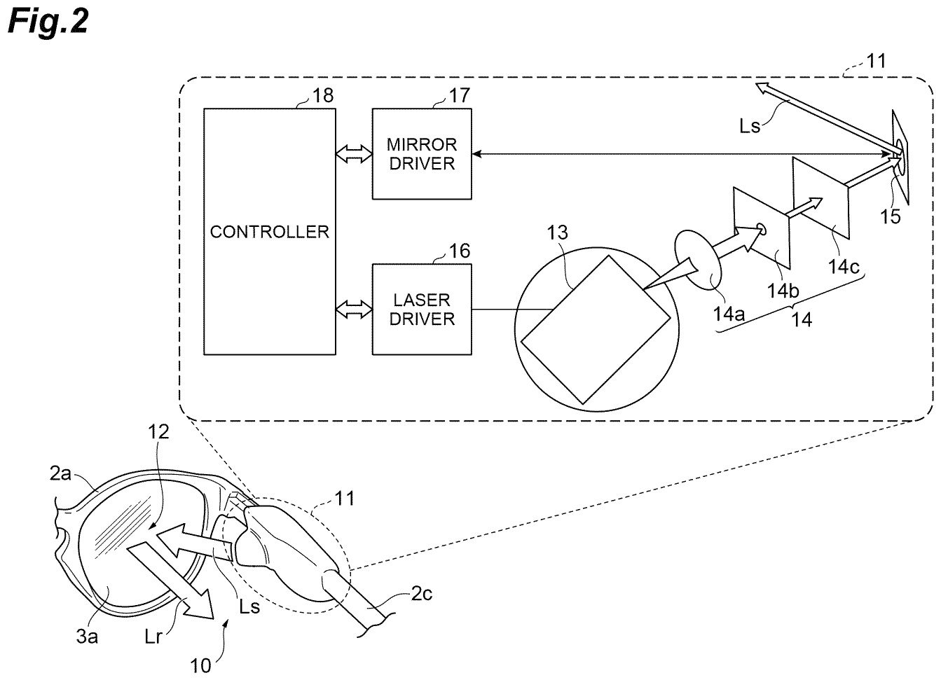

The frame 2 includes a pair of rims 2a, a bridge 2b, and a pair of temples 2c. The rim 2a is a portion for holding the lens 3. The bridge 2b is a portion connecting the pair of rims 2a. The temple 2c extends from the rim 2a and is a portion to be put on an ear of a user. The frame 2 may be a rimless frame. The lens 3 has an inner surface 3a (refer to FIG. 2) facing an eyeball of a user wearing the near-eye wearable device 1.

The retinal projection device 10 is a device for directly projecting (drawing) an image onto a retina of a user wearing the near-eye wearable device 1. The retinal projection device 10 is mounted on the near-eye wearable device 1. In the present embodiment, the near-eye wearable device 1 includes two retinal projection devices 10 in order to project an image onto both the right and left retinas, but may include only one of the retinal projection devices 10.

Next, the retinal projection device 10 will be described in detail with reference to FIG. 2. FIG. 2 is a configuration diagram schematically showing the retinal projection device shown in FIG. 1. As shown in FIG. 2, the retinal projection device 10 includes an optical engine 11 and a reflector 12.

The optical engine 11 is a device that generates laser light Ls having a color and light intensity corresponding to a pixel of an image to be projected onto the retina and emits the laser light Ls to the reflector 12. The optical engine 11 is mounted on the temple 2c. The optical engine 11 includes a laser module 13, optical components 14, a movable mirror 15, a laser driver 16, a mirror driver 17, and a controller 18.

The laser module 13 emits laser light. As the laser module 13, for example, a full-color laser module is used. The laser module 13 emits laser light having a color and light intensity corresponding to a pixel of an image to be projected onto the retina. Details of the laser module 13 will be described later.

The optical components 14 are components that optically process the laser light emitted from the laser module 13. In the present embodiment, the optical components 14 include a collimator lens 14a, a slit 14b, and a neutral density filter 14c. The collimator lens 14a, the slit 14b, and the neutral density filter 14c are arranged in this order along the optical path of the laser light. The optical components 14 may have other configurations.

The movable mirror 15 is a member for performing scanning with the laser light Ls. The movable mirror 15 is provided in a direction in which the laser light processed by the optical components 14 is emitted. The movable mirror 15 is configured to be swingable about an axis extending in the horizontal direction of the lens 3 and about an axis extending in the vertical direction of the lens 3, for example, and reflects the laser light while changing the angle in the horizontal direction and the vertical direction of the lens 3. As the movable mirror 15, for example, a micro electro mechanical systems (MEMS) mirror is used.

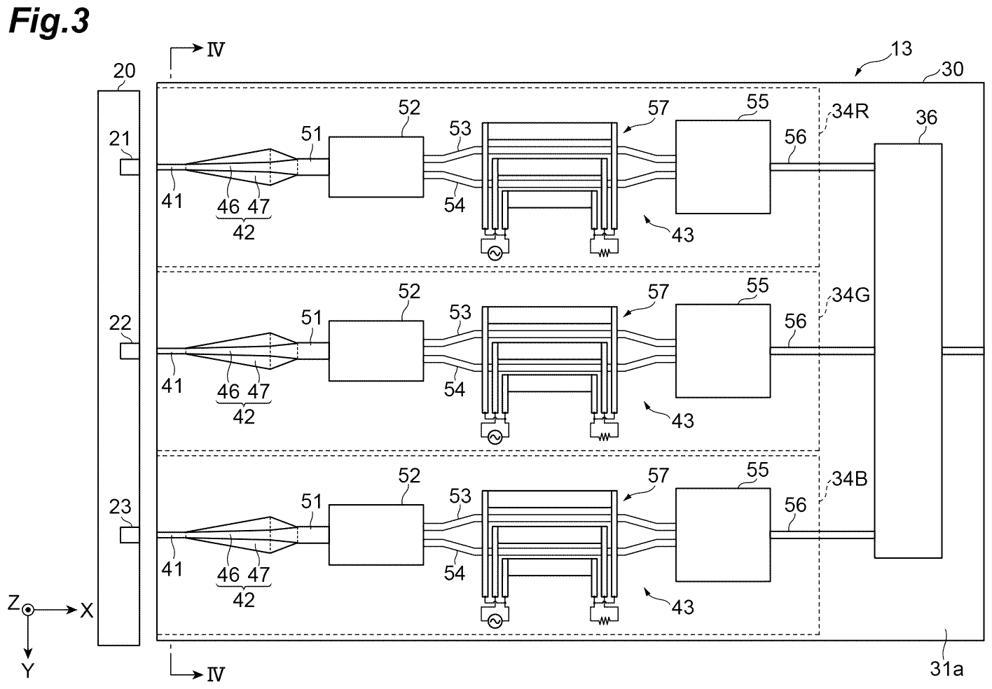

The laser driver 16 is a driving circuit for driving the laser module 13. The laser driver 16 drives the laser module 13 based on, for example, the optical power (light intensity) of the laser light and the temperature of a light source unit 20 (refer to FIG. 3) included in the laser module 13. The mirror driver 17 is a driving circuit for driving the movable mirror 15. The mirror driver 17 swings the movable mirror 15 within a predetermined angle range and at a predetermined timing. The controller 18 is a device for controlling the laser driver 16 and the mirror driver 17.

In the optical engine 11, laser light having a color and light intensity corresponding to a pixel of an image to be projected onto the retina is emitted from the laser module 13, passes through the optical components 14, and is reflected by the movable mirror 15. The laser light reflected by the movable mirror 15 is emitted to the reflector 12 as the laser light Ls.

The reflector 12 is a member that projects an image onto the retina of the user wearing the near-eye wearable device 1 by reflecting the laser light Ls having passed through the movable mirror 15 and irradiating the retina with reflected light Lr.

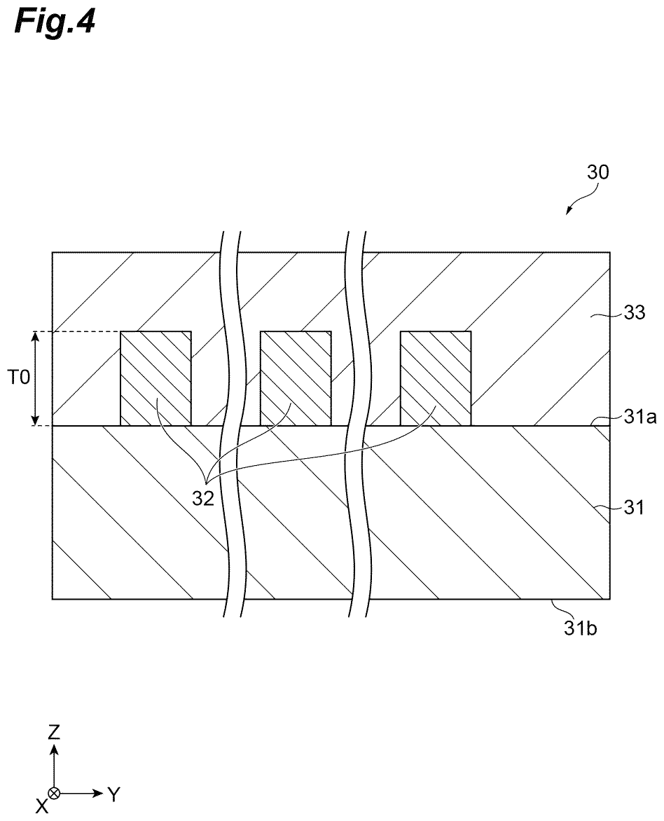

Next, the laser module 13 will be described in detail with reference to FIGS. 3 and 4. FIG. 3 is a plan view of the laser module shown in FIG. 2. FIG. 4 is a cross-sectional view taken along the line IV-IV of FIG. 3. In FIG. 3, the illustration of a cladding layer 33 is omitted for convenience of explanation. As shown in FIG. 3, the laser module 13 includes the light source unit 20 and an optical element 30.

The light source unit 20 emits visible light. The light source unit 20 includes a red laser diode 21 (first light source) for emitting red light, a green laser diode 22 (second light source) for emitting green light, and a blue laser diode 23 (third light source) for emitting blue light. The peak wavelength of the red light is, for example, in the range of 600 nm to 830 nm. The peak wavelength of the green light is, for example, in the range of 500 nm to 570 nm. The peak wavelength of the blue light is, for example, in the range of 380 nm to 490 nm. The red laser diode 21, the green laser diode 22, and the blue laser diode 23 are arranged in that order in the Y-axis direction.

In the present embodiment, the red laser diode 21 emits red light in a TM fundamental mode (hereinafter referred to as “TM0 mode”). The green laser diode 22 emits green light in the TM0 mode. The blue laser diode 23 emits blue light in the TM0 mode.

The optical element 30 multiplexes the laser lights emitted from the respective laser diodes into one laser light. The optical element 30 is, for example, a planar lightwave circuit (PLC). As shown in FIG. 4, the optical element 30 includes a substrate 31, a core layer 32, and the cladding layer 33.

The substrate 31 functions as a lower cladding layer. The substrate 31 is made of a material having a refractive index lower than that of the constituent material of the core layer 32. Examples of the constituent materials of the substrate 31 include sapphire, silicon oxide, and silicon laminated with silicon oxide. The substrate 31 includes a main surface 31a and a rear surface 31b opposite to the main surface 31a. The main surface 31a and the rear surface 31b are surfaces defined by the X-axis direction and the Y-axis direction, and intersect with the Z-axis direction (in the present embodiment, the main surface 31a and the rear surface 31b are orthogonal to the Z-axis direction). In other words, the X-axis direction and the Y-axis direction are directions along the main surface 31a.

The cladding layer 33 functions as an upper cladding layer. The cladding layer 33 covers the core layer 32 on the main surface 31a. The cladding layer 33 is provided over the entire surface of the main surface 31a. The cladding layer 33 is made of a material having a refractive index lower than that of the constituent material of the core layer 32. An example of a constituent material of the cladding layer 33 is silicon oxide (e.g., SiO₂).

The core layer 32 is provided on the main surface 31a. The core layer 32 is made of a material having an electro-optic effect. The electro-optic effect is a phenomenon in which the refractive index of a material is changed by applying an electric field to the material. An example of a constituent material of the core layer 32 is lithium niobate (LiNbO₃). In the present embodiment, the core layer 32 is made of X-cut lithium niobate, and the optical axis (C-axis) of the lithium niobate extends in the Y-axis direction. The core layer 32 includes a mode converter 34R (first mode converter), a mode converter 34G (second mode converter), a mode converter 34B (third mode converter), and a multiplexer 36.

The mode converter 34R is a mode converter that converts the polarization mode of the red light from the TM0 mode to a TE fundamental mode (hereinafter referred to as “TE0 mode”). The mode converter 34G is a mode converter that converts the polarization mode of the green light from the TM0 mode to the TE0 mode. The mode converter 34B is a mode converter that converts the polarization mode of the blue light from the TM0 mode to the TE0 mode.

The polarization mode is also referred to as a waveguide mode. The TM mode is a polarization mode in which the main component of the electric field in the cross section perpendicular to the light propagation direction is oriented perpendicular to the main surface 31a of the substrate 31. The TE mode is a polarization mode in which the main component of the electric field in the cross section perpendicular to the light propagation direction is oriented parallel to the main surface 31a of the substrate 31. The TM0 mode is a polarization mode having the highest effective refractive index among the TM modes. The TE0 mode is a polarization mode having the highest effective refractive index among the TE modes. The TE first-order mode (hereinafter referred to as “TE1 mode”) is a polarization mode having the second highest effective refractive index among the TE modes.

Each of the mode converter 34R, the mode converter 34G, and the mode converter 34B extends in the X-axis direction. The mode converter 34R, the mode converter 34G, and the mode converter 34B are arranged in that order in the Y-axis direction. The detailed configuration of each mode converter will be described later.

The multiplexer 36 multiplexes the red light, the green light, and the blue light. The multiplexer 36 multiplexes the red light emitted from the mode converter 34R, the green light emitted from the mode converter 34G, and the blue light emitted from the mode converter 34B into a single laser light to emit the laser light. The laser light contains a component having a red wavelength (red component), a component having a green wavelength (green component), and a component having a blue wavelength (blue component).

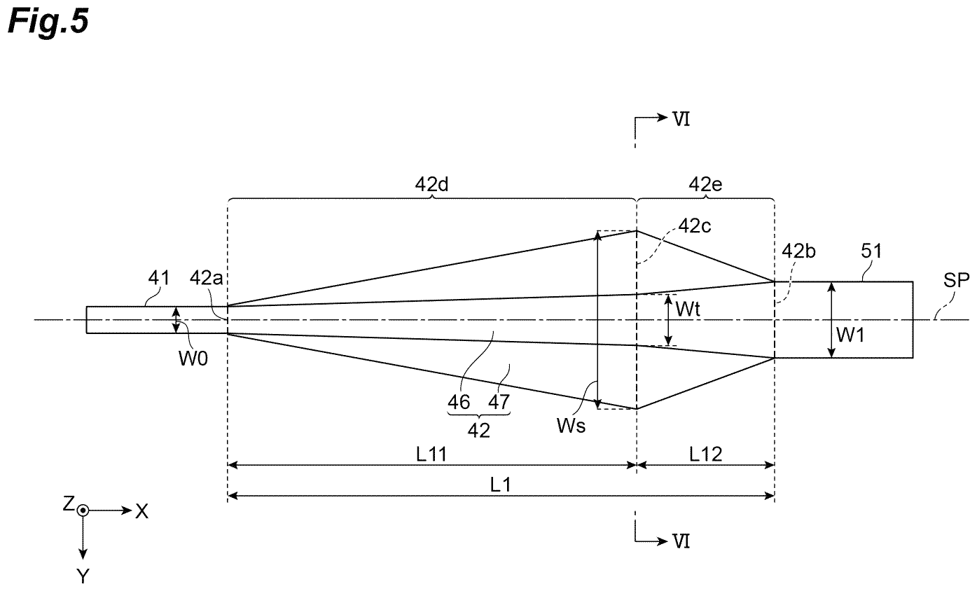

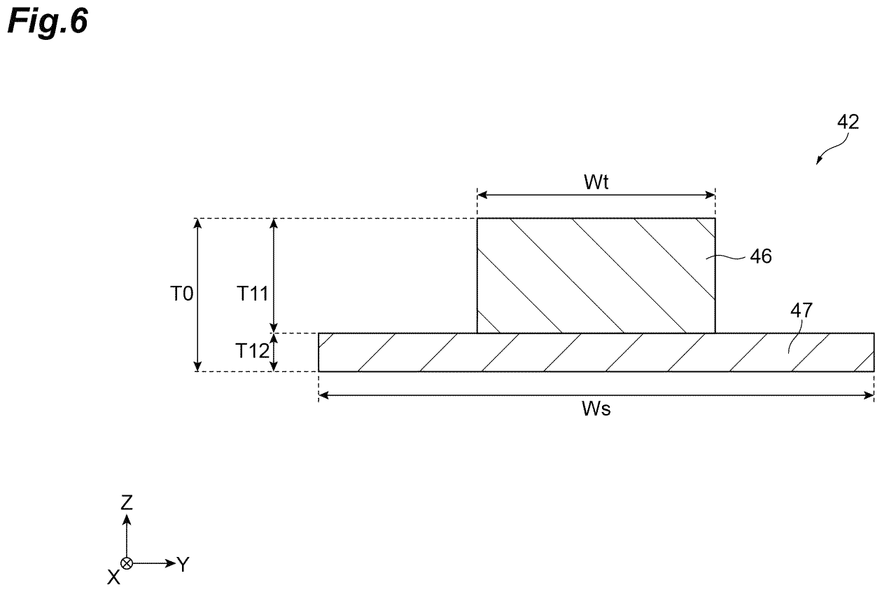

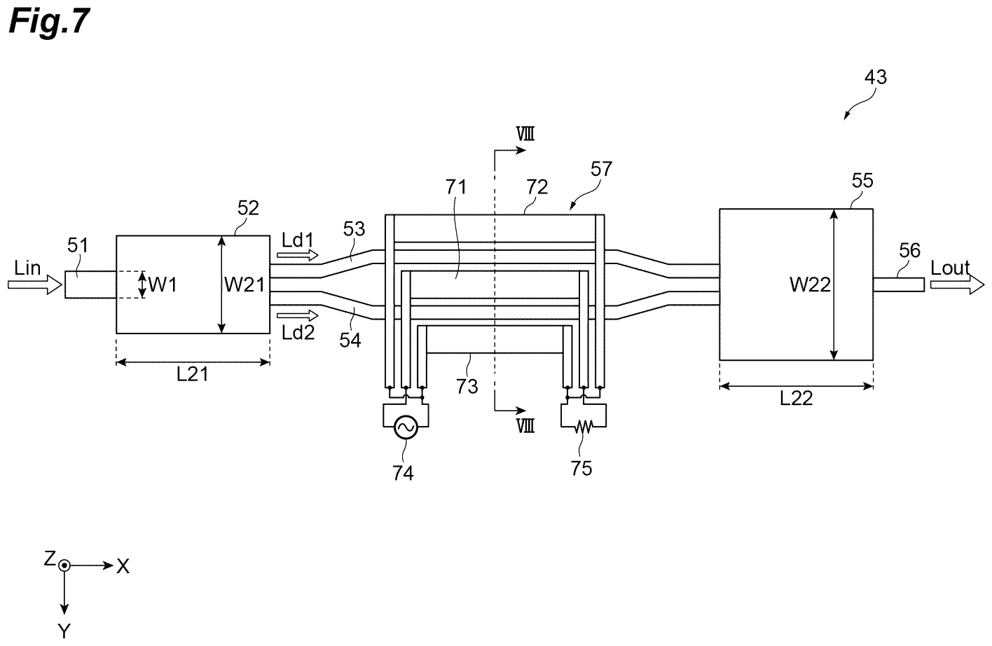

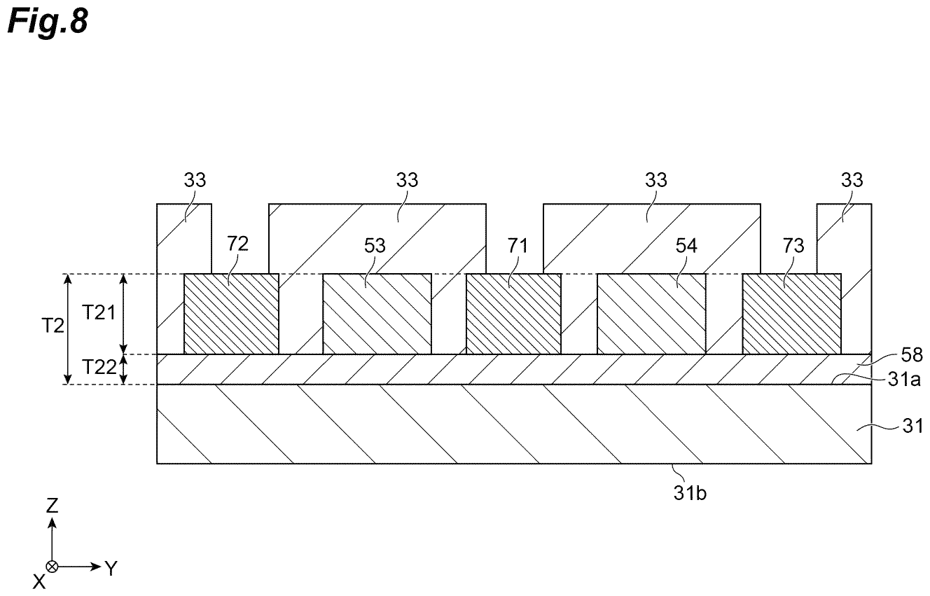

Next, the detailed configurations of the mode converters 34R, 34G, and 34B will be described with further reference to FIGS. 5 to 8. FIG. 5 is an enlarged view of a part of the mode converter shown in FIG. 3. FIG. 6 is a cross-sectional view taken along line the VI-VI of FIG. 5. FIG. 7 is an enlarged view of the modulator shown in FIG. 3. FIG. 8 is a cross-sectional view taken along the line VIII-VIII of FIG. 7. As shown in FIG. 3, each of the mode converter 34R, the mode converter 34G, and the mode converter 34B includes an incident portion 41 on which visible light is incident, a conversion portion 42 (first conversion portion) that converts the polarization mode of the visible light from the TM0 mode to the TE1 mode, and a conversion portion 43 (second conversion portion) that converts the polarization mode of the visible light from the TE1 mode to the TE0 mode. Since the mode converter 34R, the mode converter 34G, and the mode converter 34B have similar configurations, the configuration of the mode converter 34R will be described here.

As shown in FIGS. 3 and 5, the incident portion 41 is an optical waveguide positioned at one end (incident end) of the mode converter 34R in the X-axis direction. The incident portion 41 is provided on the main surface 31a and extends in the X-axis direction. The red light in TM0 mode is incident from the red laser diode 21 on one end of the incident portion 41 in the X-axis direction. The incident portion 41 transmits the red light while maintaining the polarization mode of the red light, and emits the red light in the TM0 mode to the conversion portion 42.

The cross section of the incident portion 41 intersecting (orthogonal to) the X-axis direction has a rectangular shape. The cross section may have a trapezoidal shape. The length of the incident portion 41 in the X-axis direction is, for example, 50 μm. The length of the incident portion 41 in the Y-axis direction is substantially constant over the entire length of the incident portion 41 in the X-axis direction. Hereinafter, the length in the Y-axis direction may be referred to as “width”. The width of the incident portion 41 is a width W0. The width W0 is, for example, 0.45 μm. The length of the incident portion 41 in the Z-axis direction is substantially constant over the entire length of the incident portion 41 in the X-axis direction. Hereinafter, the length in the Z-axis direction may be referred to as “height”. The height of the incident portion 41 is a height TO. The height TO is, for example, 0.7 μm.

As shown in FIGS. 3, 5 and 6, the conversion portion 42 is provided between the incident portion 41 and the conversion portion 43, and is a portion that converts the polarization mode of the visible light from the TM0 mode to the TE1 mode. The conversion portion 42 is provided on the main surface 31a. The conversion portion 42 includes a connection end 42a and a connection end 42b which are both ends in the X-axis direction. The connection end 42a is connected to the other end of the incident portion 41 in the X-axis direction. The connection end 42b is connected to one end (incident end) of the conversion portion 43 in the X-axis direction.

The conversion portion 42 is divided into a conversion region 42d and a conversion region 42e at an intermediate position 42c. The intermediate position 42c is a position between the connection end 42a and the connection end 42b in the X-axis direction. The conversion region 42d is a region from the connection end 42a to the intermediate position 42c in the conversion portion 42. The conversion region 42e is a region from the intermediate position 42c to the connection end 42b in the conversion portion 42. The length L11 of the conversion region 42d in the X-axis direction is, for example, 350 μm to 1000 μm. The length L12 of the conversion region 42e in the X-axis direction is, for example, 10 μm to 80 μm. The length L1 of the conversion portion 42 in the X-axis direction is equal to the sum of the length L11 and the length L12, and is, for example, 360 μm to 1010 μm.

The conversion portion 42 includes an upper tapered portion 46 and a lower tapered portion 47. The upper tapered portion 46 and the lower tapered portion 47 are stacked in the Z-axis direction. Specifically, the lower tapered portion 47 is provided on the main surface 31a, and the upper tapered portion 46 is provided on the lower tapered portion 47. The height of the upper tapered portion 46 is substantially constant over the entire length of the upper tapered portion 46 in the X-axis direction. The height of the upper tapered portion 46 is a height T11. The height T11 is, for example, 0.5 μm. The height of the lower tapered portion 47 is substantially constant over the entire length of the lower tapered portion 47 in the X-axis direction. The height of the lower tapered portion 47 is a height T12. The height T12 is, for example, 0.2 μm. The height of the conversion portion 42 is equal to the sum of the height of the upper tapered portion 46 and the height of the lower tapered portion 47, and is a height TO.

In the conversion region 42d, the width of the upper tapered portion 46 continuously increases from the width W0 at the connection end 42a to the width Wt toward the intermediate position 42c. The width Wt is larger than the width W0. The width Wt is, for example, 0.5 μm to 1.0 μm. The rate of increase in the width of the upper tapered portion 46 in the conversion region 42d may be substantially constant. In the conversion region 42e, the width of the upper tapered portion 46 continuously increases from the width Wt at the intermediate position 42c to the width W1 toward the connection end 42b. The width W1 is larger than the width Wt and smaller than a width Ws described later. The width W1 is, for example, 0.85 μm. The rate of increase in the width of the upper tapered portion 46 in the conversion region 42e may be substantially constant. The upper tapered portion 46 has a shape symmetric with respect to a symmetry plane SP defined by the X-axis direction and the Z-axis direction.

In the conversion region 42d, the width of the lower tapered portion 47 continuously increases from the width W0 at the connection end 42a to the width Ws toward the intermediate position 42c. The width Ws is larger than the width Wt. The width Ws is, for example, 1.0 μm to 5.0 μm. The rate of increase in the width of the lower tapered portion 47 in the conversion region 42d may be substantially constant. In the conversion region 42e, the width of the lower tapered portion 47 continuously decreases from the width Ws at the intermediate position 42c to the width W1 toward the connection end 42b. The rate of decrease in the width of the lower tapered portion 47 in the conversion region 42e may be substantially constant. The lower tapered portion 47 has a shape symmetrical with respect to the symmetry plane SP.

In the conversion portion 42 configured as described above, since the upper tapered portion 46 and the lower tapered portion 47 are stacked in the Z-axis direction, the conversion portion 42 has an asymmetry in the Z-axis direction. Here, the term “asymmetry in the Z-axis direction” means that, with respect to a symmetry plane that passes through the center of the conversion portion 42 in the Z-axis direction and is orthogonal to the Z-axis direction, two portions separated by the symmetry plane are not plane-symmetric.

In the conversion portion 42, the effective refractive index of the TM0 mode and the effective refractive index of the TE1 mode approach and then intersect each other as the distance from the connection end 42a increases in the X-axis direction, so that conversion between the TM0 mode and the TE1 mode is induced. Accordingly, when the red light in the TM0 mode is incident on the connection end 42a, the polarization mode of the red light is converted from the TM0 mode to the TE1 mode in the conversion portion 42. In the conversion region 42d, the width of the lower tapered portion 47 increases more than the width of the upper tapered portion 46 as the distance from the connection end 42a increases. This configuration makes it possible to improve the conversion efficiency while reducing the length of the conversion portion 42 in the X-axis direction. In the conversion region 42e, the width of the lower tapered portion 47 decreases as approaching the connection end 42b, and the width of the upper tapered portion 46 and the width of the lower tapered portion 47 become equal at the connection end 42b. This configuration makes it possible to further improve the conversion efficiency.

For example, about 50% to 60% of the conversion from the TM0 mode to the TE1 mode is performed in the conversion region 42d, and about 20% to 30% of the conversion from the TM0 mode to the TE1 mode is performed in the conversion region 42e. On the other hand, the effective refractive index of the TE0 mode is sufficiently far from the effective refractive indices of the TM0 mode and the TE1 mode over the entire length of the conversion portion 42 in the X-axis direction. Accordingly, when the red light in the TE0 mode is incident on the connection end 42a, the polarization mode of the red light is maintained in the TE0 mode.

As shown in FIG. 7, the conversion portion 43 is a Mach-Zehnder type optical waveguide and includes an input waveguide 51, a splitting portion 52, a branch waveguide 53 (first branch waveguide), a branch waveguide 54 (second branch waveguide), a coupling portion 55, an output waveguide 56, a phase adjustment unit (phase adjuster) 57, and a slab 58 (see FIG. 8).

As shown in FIG. 8, the slab 58 is provided on the main surface 31a. The slab 58 has a flat plate shape. The height of the slab 58 is a height T22. The height T22 is, for example, 0.2 μm.

The input waveguide 51 is an optical waveguide positioned at one end (incident end) of the conversion portion 43 in the X-axis direction. The input waveguide 51 is provided on the slab 58 and extends in the X-axis direction. One end of the input waveguide 51 in the X-axis direction is connected to the connection end 42b. The other end of the input waveguide 51 in the X-axis direction is connected to the input end of the splitting portion 52. The red light in TE1 mode (hereinafter, sometimes referred to as “light Lin”) is incident on the input waveguide 51 from the conversion portion 42. The input waveguide 51 transmits the light Lin while maintaining the polarization mode of the light Lin, and emits the light Lin in the TE1 mode to the splitting portion 52.

The cross section of the input waveguide 51 intersecting (orthogonal to) the X-axis direction has a rectangular shape. The cross section may have a trapezoidal shape. The length of the input waveguide 51 in the X-axis direction is, for example, 50 μm. The width of the input waveguide 51 is substantially constant over the entire length of the input waveguide 51 in the X-axis direction. The width of the input waveguide 51 is the width W1. The height of the input waveguide 51 is substantially constant over the entire length of the input waveguide 51 in the X-axis direction. The height of the input waveguide 51 is a height T21. The height T21 is, for example, 0.5 μm.

The splitting portion 52 splits the light Lin in the TE1 mode incident from the input waveguide 51 into split light Ld1 (first split light) in the TE0 mode and split light Ld2 (second split light) in the TE0 mode. The split light Ld1 and the split light Ld2 are opposite in phase to each other. The light intensity of the split light Ld1 and the light intensity of the split light Ld2 are substantially half (50%) of the light intensity of the light Lin. In the present embodiment, the splitting portion 52 is composed of a multimode interferometer (MMI). The splitting portion 52 may be composed of a Y-branch waveguide or may be composed of a directional coupler. The splitting portion 52 is provided on the slab 58. The splitting portion 52 emits the split light Ld1 to the branch waveguide 53 and emits the split light Ld2 to the branch waveguide 54.

The cross section of the splitting portion 52 intersecting (orthogonal to) the X-axis direction has a rectangular shape. The cross section may have a trapezoidal shape. The length L21 of the splitting portion 52 in the X-axis direction is, for example, 40 μm to 64 μm. The splitting portion 52 has a rectangular shape when viewed from the Z-axis direction. The width of the splitting portion 52 is substantially constant over the entire length of the splitting portion 52 in the X-axis direction. The width of the splitting portion 52 is a width W21. The width W21 is, for example, 3.0 μm to 3.5 μm. The height of the splitting portion 52 is substantially constant over the entire length of the splitting portion 52 in the X-axis direction. The height of the splitting portion 52 is the height T21.

The branch waveguide 53 is an optical waveguide through the split light Ld1 propagates. The branch waveguide 54 is an optical waveguide through which the split light Ld2 propagates. Each of the branch waveguides 53 and 54 extends in the X-axis direction from the splitting portion 52 to the coupling portion 55. The branch waveguides 53 and 54 are provided on the slab 58 and are arranged in the Y-axis direction. The branch waveguides 53 and 54 extend in the vicinity of the splitting portion 52 so as to be separated from each other in the Y-axis direction as the distance from the splitting portion 52 increases, and extend in the vicinity of the coupling portion 55 so as to be closer to each other in the Y-axis direction as the distance to the coupling portion 55 decreases. The branch waveguides 53 and 54 extend substantially in parallel between the vicinity of the splitting portion 52 and the vicinity of the coupling portion 55.

One end of the branch waveguide 53 in the X-axis direction is connected to the emission end of the splitting portion 52. The other end of the branch waveguide 53 in the X-axis direction is connected to the incident end of the coupling portion 55. The split light Ld1 in the TE0 mode is incident on one end of the branch waveguide 53 from the splitting portion 52. The branch waveguide 53 transmits the split light Ld1 while maintaining the polarization mode of the split light Ld1, and emits the split light Ld1 in the TE0 mode from the other end to the coupling portion 55.

One end of the branch waveguide 54 in the X-axis direction is connected to another emission end of the splitting portion 52. The other end of the branch waveguide 54 in the X-axis direction is connected to another incident end of the coupling portion 55. The split light Ld2 in the TE0 mode is incident on one end of the branch waveguide 54 from the splitting portion 52. The branch waveguide 54 transmits the split light Ld2 while maintaining the polarization mode of the split light Ld2, and emits the split light Ld2 in the TE0 mode from the other end to the coupling portion 55.

The cross section of each of the branch waveguides 53 and 54 intersecting (orthogonal to) the X-axis direction has a rectangular shape. The cross section may have a trapezoidal shape. The length of the branch waveguide 53 in the X-axis direction is, for example, 11 mm. The width of the branch waveguide 53 is substantially constant over the entire length of the branch waveguide 53. The width of the branch waveguide 53 is, for example, 0.8 μm. The height of the branch waveguide 53 is substantially constant over the entire length of the branch waveguide 53. The height of the branch waveguide 53 is the height T21. The length of the branch waveguide 54 in the X-axis direction is substantially the same as the length of the branch waveguide 53 in the X-axis direction. The width of the branch waveguide 54 is substantially the same as the width of the branch waveguide 53 and is substantially constant over the entire length of the branch waveguide 54. The height of the branch waveguide 54 is substantially the same as the height of the branch waveguide 53 and is substantially constant over the entire length of the branch waveguide 54.

The coupling portion 55 couples the split light Ld1 that has propagated through the branch waveguide 53 and the split light Ld2 that has propagated through the branch waveguide 54 to emit the red light in the TE0 mode (hereinafter, sometimes referred to as “light Lout”). In the present embodiment, the coupling portion 55 is composed of an MMI. The coupling portion 55 may be composed of a Y-branch waveguide or may be composed of a directional coupler. The coupling portion 55 is provided on the slab 58. The coupling portion 55 emits the light Lout to the output waveguide 56.

The cross section of the coupling portion 55 intersecting (orthogonal to) the X-axis direction has a rectangular shape. The cross section may have a trapezoidal shape. The length L22 of the coupling portion 55 in the X-axis direction is, for example, 63 μm to 100 μm. The coupling portion 55 has a rectangular shape when viewed from the Z-axis direction. The width of the coupling portion 55 is substantially constant over the entire length of the coupling portion 55 in the X-axis direction. The width of the coupling portion 55 is a width W22. The width W22 is, for example, 6 μm to 10 μm. The height of the coupling portion 55 is substantially constant over the entire length of the coupling portion 55 in the X-axis direction. The height of the coupling portion 55 is the height T21.

The output waveguide 56 is an optical waveguide positioned at the other end (emission end) of the conversion portion 43 in the X-axis direction. The output waveguide 56 is provided on the slab 58 and extends in the X-axis direction. One end of the output waveguide 56 in the X-axis direction is connected to the emission end of the coupling portion 55. The other end of the output waveguide 56 in the X-axis direction is connected to the incident end of the multiplexer 36. The light Lout in the TE0 mode is incident on the output waveguide 56 from the coupling portion 55. The output waveguide 56 transmits the light Lout while maintaining the polarization mode of the light Lout, and emits the light Lout in the TE0 mode to the multiplexer 36.

The cross section of the output waveguide 56 intersecting (orthogonal to) the X-axis direction has a rectangular shape. The cross section may have a trapezoidal shape. The length of the output waveguide 56 in the X-axis direction is, for example, 50 μm. The width of the output waveguide 56 is substantially constant over the entire length of the output waveguide 56 in the X-axis direction. The width of the output waveguide 56 is substantially the same as the width of the branch waveguide 53. The height of the output waveguide 56 is substantially constant over the entire length of the output waveguide 56 in the X-axis direction. The height of the output waveguide 56 is the height T21.

The phase adjustment unit 57 adjusts the phase difference between the split light Ld1 and the split light Ld2. In the present embodiment, the phase adjustment unit 57 includes a signal electrode 71, a ground electrode 72 (first ground electrode), a ground electrode 73 (second ground electrode), a signal source 74, and a termination resistor 75.

Each of the signal electrode 71, the ground electrode 72, and the ground electrode 73 is provided on the slab 58 and extends in the X-axis direction. The signal electrode 71 is disposed between the branch waveguides 53 and 54. The ground electrodes 72 and 73 are arranged so as to sandwich the branch waveguides 53 and 54 in the Y-axis direction. In other words, the ground electrode 72, the branch waveguide 53, the signal electrode 71, the branch waveguide 54, and the ground electrode 73 are arranged in this order in the Y-axis direction at substantially equal intervals. The cladding layer 33 does not cover a part of the signal electrode 71, a part of the ground electrode 72, and a part of the ground electrode 73, and a part of the upper surface of the signal electrode 71, a part of the upper surface of the ground electrode 72, and a part of the upper surface of the ground electrode 73 are exposed.

The cross section of each of the signal electrode 71, the ground electrode 72, and the ground electrode 73 intersecting (orthogonal to) the X-axis direction has a rectangular shape. The length of the signal electrode 71 in the X-axis direction is, for example, 10 mm. The width of the signal electrode 71 is substantially constant over the entire length of the signal electrode 71 in the X-axis direction. The width of the signal electrode 71 is, for example, 5 μm. The height of the signal electrode 71 is substantially constant over the entire length of the signal electrode 71 in the X-axis direction. The height of the signal electrode 71 is the height T21.

The length of the ground electrode 72 in the X-axis direction is, for example, 10 mm. The width of the ground electrode 72 is substantially constant over the entire length of the ground electrode 72 in the X-axis direction. The width of the ground electrode 72 is, for example, 200 μm. The height of the ground electrode 72 is substantially constant over the entire length of the ground electrode 72. The height of the ground electrode 72 is the height T21. The length of the ground electrode 73 in the X-axis direction is substantially the same as the length of the ground electrode 72 in the X-axis direction. The width of the ground electrode 73 is substantially the same as the width of the ground electrode 72, and is substantially constant over the entire length of the ground electrode 73 in the X-axis direction. The height of the ground electrode 73 is substantially the same as the height of the ground electrode 72 and is substantially constant over the entire length of the ground electrode 73.

The signal source 74 supplies a modulation signal for modulating the light intensity of the red light propagating through the conversion portion 43. One end of the signal source 74 is electrically connected to one end of the signal electrode 71, and the other end of the signal source 74 is electrically connected to one end of the ground electrode 72 and one end of the ground electrode 73.

The termination resistor 75 electrically terminates the modulation signal. One end of the termination resistor 75 is electrically connected to the other end of the signal electrode 71, and the other end of the termination resistor 75 is electrically connected to the other end of the ground electrode 72 and the other end of the ground electrode 73.

In the conversion portion 43 configured as described above, when the light Lin in the TE1 mode is incident on the input waveguide 51, the light Lin is split by the splitting portion 52 into the split light Ld1 in the TE0 mode and the split light Ld2 in the TE0 mode which are opposite in phase to each other, and the split light Ld1 and the split light Ld2 are emitted to and propagate through the branch waveguides 53 and 54, respectively. When the modulation signal is supplied from the signal source 74 to the signal electrode 71, the ground electrode 72, and the ground electrode 73, a potential difference corresponding to the modulation signal is generated between the signal electrode 71 and the ground electrode 72 and between the signal electrode 71 and the ground electrode 73, and a voltage in the Y-axis direction is applied to the branch waveguides 53 and 54.

Accordingly, the refractive index of the branch waveguide 53 is changed in accordance with the voltage applied to the branch waveguide 53, and the refractive index of the branch waveguide 54 is changed in accordance with the voltage applied to the branch waveguide 54. In the present embodiment, the voltage applied to the branch waveguide 54 has the polarity opposite to that of the voltage applied to the branch waveguide 53 and the same magnitude as the voltage applied to the branch waveguide 53. Accordingly, a difference is generated between the refractive index of the branch waveguide 53 and the refractive index of the branch waveguide 54, and the phase difference between the split light Ld1 and the split light Ld2 is changed from 180° in accordance with the difference. Then, the split light Ld1 that has propagated through the branch waveguide 53 and the split light Ld2 that has propagated through the branch waveguide 54 are coupled at the coupling portion 55.

At this time, the light intensity of the coupled light Lout varies in accordance with the phase difference between the split light Ld1 and the split light Ld2. For example, when the phase difference between the split light Ld1 and the split light Ld2 is 180°, the light intensity of the light Lout is 0%, and the light Lout is not output. When the split light Ld1 and the split light Ld2 are in phase, the light intensity of the light Lout is substantially the same (100%) as the light intensity of the light Lin. Accordingly, the light intensity of the light Lout can be adjusted in the range of 0% to 100% of the light intensity of the light Lin. Then, the light Lout is emitted to the multiplexer 36 via the output waveguide 56.

In the laser module 13 and the optical element 30 described above, the polarization mode of the visible light is converted from the TM0 mode to the TE1 mode by the conversion portion 42, and the polarization mode of the visible light is converted from the TE1 mode to the TE0 mode by the conversion portion 43. Accordingly, the polarization mode of the visible light can be converted from the TM0 mode to the TE0 mode. Further, in the conversion portion 43, the light Lin in the TE1 mode incident from the conversion portion 42 is split into the split light Ld1 and Ld2 in the TE0 mode having opposite phases, and the phase difference between the split light Ld1 and the split light Ld2 is adjusted. Then, by coupling the split light Ld1 and Ld2, the light Lout in the TE0 mode is emitted. Since the light intensity of the light Lout emitted from the coupling portion 55 can be changed in accordance with the phase difference between the split light Ld1 and the split light Ld2, the conversion portion 43 can also function as an optical modulator. Accordingly, since there is no need to provide an optical modulator, the laser module 13 and the optical element 30 can be reduced in size.

It is known that the electro-optical characteristics of a device made of a material having an electro-optic effect, such as lithium niobate, depend on the application direction of a voltage and the polarization direction of light. For example, a large electro-optic effect can be obtained when a voltage is applied in the C-axis direction of a material having an electro-optic effect and the direction of the main electric field of light propagating through the device aligns with the C-axis direction. In the laser module 13 and the optical element 30, the core layer 32 is made of X-cut lithium niobate, and the C-axis of the lithium niobate extends in the Y-axis direction.

On the other hand, the branch waveguide 53 is disposed between the signal electrode 71 and the ground electrode 72, and the branch waveguide 54 is disposed between the signal electrode 71 and the ground electrode 73. Therefore, when a voltage is applied between the signal electrode 71 and the ground electrode 72, a voltage is applied to the branch waveguide 53 in the Y-axis direction. Similarly, when a voltage is applied between the signal electrode 71 and the ground electrode 73, a voltage is applied to the branch waveguide 54 in the Y-axis direction. Further, the light Lin in the TE1 mode is split into the split light Ld1 in the TE0 mode and the split light Ld2 in the TE0 mode by the splitting portion 52, and the split light Ld1 is emitted to the branch waveguide 53, and the split light Ld2 is emitted to the branch waveguide 54.

Accordingly, in the branch waveguide 53, a voltage is applied in the C-axis direction of the material constituting the core layer 32, and the direction of the main electric field of the split light Ld1 propagating through the branch waveguide 53 aligns with the C-axis direction, so that a large electro-optic effect can be obtained. Similarly, in the branch waveguide 54, a voltage is applied in the C-axis direction of the material constituting the core layer 32, and the direction of the main electric field of the split light Ld2 propagating through the branch waveguide 54 aligns with the C-axis direction, so that a large electro-optic effect can be obtained. As a result, the modulation efficiency in the conversion portion 43 can be improved.

The length of the splitting portion 52 in the X-axis direction may be 40 μm or more and 64 μm or less. The width of the splitting portion 52 may be 3.0 μm or more and 3.5 μm or less. In this case, it is possible to reduce the loss of light intensity in the conversion from the TE1 mode to the TE0 mode. Accordingly, the conversion efficiency from the TE1 mode to the TE0 mode can be improved.

In order to output full-color laser light by multiplexing the red light, the green light, and the blue light, it is necessary to adjust the light intensity of light of each color corresponding to the output color. In order to change the light intensity of each color light in the light source unit 20, a large drive current is required. In the laser module 13 and the optical element 30, the light intensity of the red light is modulated by the conversion portion 43 of the mode converter 34R, the light intensity of the green light is modulated by the conversion portion 43 of the mode converter 34G, and the light intensity of the blue light is modulated by the conversion portion 43 of the mode converter 34B. Accordingly, full-color laser light can be output without requiring a large drive current.

The optical element and the laser module according to the present disclosure are not limited to the above-described embodiments.

For example, the laser module 13 may be applied to a device other than the near-eye wearable device 1.

The optical element 30 is not required to include the cladding layer 33. In this case, the air layer can function as the upper cladding layer.

The optical element 30 only needs to include one mode converter. In other words, the core layer 32 only needs to include one mode converter for converting the polarization mode of the visible light from the TM0 mode to the TE0 mode.

The light emitted from the light source unit 20 is not limited to visible light. In this case, the core layer 32 includes a mode converter for converting the polarization mode of light from the TM0 mode to the TE0 mode.

The structure of the conversion portion 42 is not limited to the structure in which the upper tapered portion 46 and the lower tapered portion 47 are stacked in the Z-axis direction. The conversion portion 42 is only required to be capable of converting the polarization mode of light from the TM0 mode to the TE1 mode.

### EXAMPLES

Hereinafter, the present disclosure will be described in more detail with reference to Examples in order to explain the above effects. The present disclosure is not limited to these examples.

### <Evaluation of Conversion Loss in Mode Converter>

The conversion losses in the mode converters having the structures of Examples 1 to 7 were calculated. In the mode converters of Examples 1 to 7, the same structures as those of the mode converters 34R, 34G, and 34B shown in FIG. 3 were used. As shown in Table 1, for each color wavelength, the width W0, the width Wt, the width Ws, the width W1, the width W21, the width W22, the length L11, the length L12, the length L21, and the length L22 were set. In Examples 1 to 7, the height T11 was set to 0.5 μm, the height T12 was set to 0.2 μm, the height T21 was set to 0.5 μm, and the height T22 was set to 0.2 μm. A voltage was applied between the signal electrode 71 and the ground electrode 72 so that the split light Ld1 and the split light Ld2 were in phase. Table 1 shows the calculation results of the conversion loss.

TABLE 1

| | Wavelength | | W0 | Wt | Ws | W1 | L1 | L11 | L12 | Loss | L21 | W21 | L22 | W22 | Loss | Total Loss |
|---|---|---|---|---|---|---|---|---|---|---|---|---|---|---|---|---|
| | Color | nm | μm | μm | μm | μm | μm | μm | μm | dB | μm | μm | μm | μm | dB | dB |
| Example 1 | R | 637 | 0.45 | 0.80 | 3.0 | 0.85 | 560 | 500 | 60 | 1.1 | 40 | 3.5 | 63 | 6 | 1.8 | 2.9 |
| Example 2 | R | 637 | 0.45 | 0.80 | 3.0 | 0.85 | 560 | 500 | 60 | 1.1 | 42 | 3.5 | 63 | 6 | 1.5 | 2.6 |
| Example 3 | G | 520 | 0.45 | 0.80 | 2.0 | 0.85 | 460 | 400 | 60 | 1.7 | 55 | 3.5 | 80 | 6 | 1.0 | 2.7 |
| Example 4 | B | 455 | 0.45 | 0.55 | 1.3 | 0.85 | 450 | 400 | 50 | 1.7 | 64 | 3.5 | 94 | 6 | 1.0 | 2.7 |
| Example 5 | B | 455 | 0.45 | 0.55 | 1.3 | 0.85 | 450 | 400 | 50 | 1.7 | 64 | 3.5 | 100 | 6 | 1.5 | 3.2 |
| Example 6 | R | 637 | 0.45 | 0.80 | 3.0 | 0.85 | 560 | 500 | 60 | 1.1 | 42 | 3.0 | 63 | 6 | 2.0 | 3.1 |
| Example 7 | R | 637 | 0.45 | 0.80 | 3.0 | 0.85 | 560 | 500 | 60 | 1.1 | 42 | 3.5 | 63 | 10 | 2.3 | 3.4 |

In Examples 1 to 7, a relatively small loss of about 2.6 dB to 3.4 dB occurred. From this, it can be understood that the conversion loss is reduced and the conversion efficiency is improved. The split efficiency depends on the respective dimensions (length L21 and width W21) of the splitting portion 52, and the coupling (multiplexing) efficiency depends on the respective dimensions (length L22 and width W22) of the coupling portion 55. In Examples 1 to 7, the length L21 was in the range of 40 μm or more and 64 μm or less, and the width W21 was in the range of 3.0 μm or more and 3.5 μm or less. The length L22 was in the range of 63 μm or more and 100 μm or less, and the width W22 was in the range of 6 μm or more and 10 μm or less. In this case, it can be understood that the conversion efficiency is improved.

### (Additional Statements)

### [Clause 1]

An optical element comprising:
a substrate including a main surface; and
a core layer provided on the main surface and made of a material having an electro-optic effect,
wherein the core layer comprises a mode converter configured to convert a polarization mode of light from a TM0 mode to a TE0 mode,
wherein the mode converter comprises:
a first conversion portion configured to convert the polarization mode of the light from the TM0 mode to a TE1 mode; and
a second conversion portion configured to convert the polarization mode of the light from the TE1 mode to the TE0 mode,
wherein the second conversion portion comprises:
a splitting portion configured to split the light in the TE1 mode incident from the first conversion portion into first split light in the TE0 mode and second split light in the TE0 mode, the first split light and the second split light being in opposite phases;
a first branch waveguide extending in a first direction along the main surface, through which the first split light propagates;
a second branch waveguide extending in the first direction, through which the second split light propagates;
a coupling portion configured to couple the first split light that has propagated through the first branch waveguide and the second split light that has propagated through the second branch waveguide to emit the light in the TE0 mode; and
a phase adjustment unit configured to adjust a phase difference between the first split light and the second split light, and
wherein the first branch waveguide and the second branch waveguide are arranged in a second direction intersecting the first direction.

### [Clause 2]

The optical element according to clause 1,
wherein the phase adjustment unit comprises:
a signal electrode disposed between the first branch waveguide and the second branch waveguide; and
a first ground electrode and a second ground electrode disposed so as to sandwich the first branch waveguide and the second branch waveguide in the second direction,
wherein an optical axis of the material constituting the core layer extends in the second direction.

### [Clause 3]

The optical element according to clause 1 or 2,
wherein the light is visible light.

### [Clause 4]

The optical element according to clause 3,
wherein a length of the splitting portion in the first direction is 40 μm or more and 64 μm or less, and
wherein a length of the splitting portion in the second direction is 3.0 μm or more and 3.5 μm or less.

### [Clause 5]

The optical element according to clause 3 or 4,
wherein the core layer further comprises:
a first mode converter which is the mode converter configured to convert a polarization mode of red light from the TM0 mode to the TE0 mode;
a second mode converter which is the mode converter configured to convert a polarization mode of green light from the TM0 mode to the TE0 mode;
a third mode converter which is the mode converter configured to convert a polarization mode of blue light from the TM0 mode to the TE0 mode; and
a multiplexer configured to multiplex the red light, the green light, and the blue light to emit laser light.

### [Clause 6]

A laser module comprising:
the optical element according to clause 5;
a first light source configured to emit the red light in the TM0 mode;
a second light source configured to emit the green light in the TM0 mode; and
a third light source configured to emit the blue light in the TM0 mode.

What is claimed is:

1. An optical element comprising:
a substrate including a main surface; and
a core layer provided on the main surface and made of a material having an electro-optic effect,
wherein the core layer comprises a mode converter configured to convert a polarization mode of light from a TM0 mode to a TE0 mode,
wherein the mode converter comprises:
a first conversion portion configured to convert the polarization mode of the light from the TM0 mode to a TE1 mode; and
a second conversion portion configured to convert the polarization mode of the light from the TE1 mode to the TE0 mode,
wherein the second conversion portion comprises:
a splitting portion configured to split the light in the TE1 mode incident from the first conversion portion into first split light in the TE0 mode and second split light in the TE0 mode, the first split light and the second split light being in opposite phases;
a first branch waveguide extending in a first direction along the main surface, through which the first split light propagates;
a second branch waveguide extending in the first direction, through which the second split light propagates;
a coupling portion configured to couple the first split light that has propagated through the first branch waveguide and the second split light that has propagated through the second branch waveguide to emit the light in the TE0 mode; and
a phase adjustment unit configured to adjust a phase difference between the first split light and the second split light, and
wherein the first branch waveguide and the second branch waveguide are arranged in a second direction intersecting the first direction.

2. The optical element according to claim 1,
wherein the phase adjustment unit comprises:
a signal electrode disposed between the first branch waveguide and the second branch waveguide; and
a first ground electrode and a second ground electrode disposed so as to sandwich the first branch waveguide and the second branch waveguide in the second direction,
wherein an optical axis of the material constituting the core layer extends in the second direction.

3. The optical element according to claim 1,
wherein the light is visible light.

4. The optical element according to claim 3,
wherein a length of the splitting portion in the first direction is 40 μm or more and 64 μm or less, and
wherein a length of the splitting portion in the second direction is 3.0 μm or more and 3.5 μm or less.

5. The optical element according to claim 3,
wherein the core layer further comprises:
a first mode converter which is the mode converter configured to convert a polarization mode of red light from the TM0 mode to the TE0 mode;
a second mode converter which is the mode converter configured to convert a polarization mode of green light from the TM0 mode to the TE0 mode;
a third mode converter which is the mode converter configured to convert a polarization mode of blue light from the TM0 mode to the TE0 mode; and
a multiplexer configured to multiplex the red light, the green light, and the blue light to emit laser light.

6. A laser module comprising:
the optical element according to claim 5;
a first light source configured to emit the red light in the TM0 mode;
a second light source configured to emit the green light in the TM0 mode; and
a third light source configured to emit the blue light in the TM0 mode.
